(19) United States
(12) Patent Application Publication
(10) Pub. No.: US 2015/0255707 A1
(43) Pub. Date: Sep. 10, 2015

(54) MAGNETIC MEMORY DEVICE

(71) Applicant: Yoshinori KUMURA, Seoul (KR)

(72) Inventor: Yoshinori KUMURA, Seoul (KR)

(21) Appl. No.: 14/331,977

(22) Filed: Jul. 15, 2014

Related U.S. Application Data
(60) Provisional application No. 61/949,883, filed on Mar. 7, 2014.

(51) Int. Cl. H01L 43/02

(52) U.S. Cl. CPC H01L 43/02

(57) ABSTRACT

According to one embodiment, a magnetic memory device includes a first electrode, a second electrode having magnetism and having a major surface facing a major surface of the first electrode, a third electrode having a major surface facing the major surface of the first electrode and located away from the second electrode, and a movable member having magnetism and located between the first and second electrodes and between the first and third electrodes, the movable member being able to be brought into contact with the first electrode and being able to be selectively brought into contact with one of the second and third electrodes.

### CROSS-REFERENCE TO RELATED APPLICATIONS

This application claims the benefit of U.S. Provisional Application No. 61/949,883, filed Mar. 7, 2014, the entire contents of which are incorporated herein by reference.

### FIELD

Embodiments described herein relate generally to a magnetic memory device.

### BACKGROUND

As one of magnetic memory devices, a magnetic memory device of a Spin Transfer Torque (STT) scheme has been proposed.

However, in the magnetic memory device of the STT scheme, sufficient write current, signal level or tunnel barrier film reliability cannot always be secured. Because of this, a magnetic memory device of a satisfactory performance is hard to obtain.

There is a demand for a new magnetic memory device having a satisfactory performance.

### BRIEF DESCRIPTION OF THE DRAWINGS

FIG. 1 is a schematic view showing the structure of a magnetic memory device according to a first embodiment;

FIG. 2 is a schematic view showing, in more detail, the structure of the magnetic memory device according to the first embodiment;

FIG. 3 is a circuit diagram for explaining the principle of the magnetic memory device of the first embodiment;

FIG. 4 is a schematic view showing a state of a movable member during a read operation in the first embodiment;

FIG. 5 is a schematic view showing another state of the movable member during the read operation in the first embodiment;

FIG. 6 is a schematic view showing a state of the movable member during a write operation in the first embodiment;

FIG. 7 is a schematic view showing another state of the movable member during the write operation in the first embodiment;

FIG. 8 is a circuit diagram showing a first circuit structure example of the magnetic memory device of the first embodiment;

FIG. 9 is a circuit diagram showing a second circuit structure example of the magnetic memory device of the first embodiment;

FIG. 10 schematically shows a part of a process of manufacturing the magnetic memory device of the first embodiment;

FIG. 11 schematically shows another part of the process of manufacturing the magnetic memory device of the first embodiment;

FIG. 12 schematically shows a part of the process of manufacturing the magnetic memory device of the first embodiment;

FIG. 13 schematically shows a part of the process of manufacturing the magnetic memory device of the first embodiment;

FIG. 14 schematically shows a part of the process of manufacturing the magnetic memory device of the first embodiment;

FIG. 15 schematically shows a part of the process of manufacturing the magnetic memory device of the first embodiment;

FIG. 16 schematically shows a part of the process of manufacturing the magnetic memory device of the first embodiment;

FIG. 17 schematically shows a part of the process of manufacturing the magnetic memory device of the first embodiment;

FIG. 18 schematically shows a part of the process of manufacturing the magnetic memory device of the first embodiment;

FIG. 19 schematically shows a part of the process of manufacturing the magnetic memory device of the first embodiment;

FIG. 20 schematically shows a part of the process of manufacturing the magnetic memory device of the first embodiment;

FIG. 21 schematically shows a part of the process of manufacturing the magnetic memory device of the first embodiment;

FIG. 22 schematically shows a part of the process of manufacturing the magnetic memory device of the first embodiment;

FIG. 23 schematically shows a part of the process of manufacturing the magnetic memory device of the first embodiment;

FIG. 24 schematically shows a part of the process of manufacturing the magnetic memory device of the first embodiment;

FIG. 25 schematically shows a part of the process of manufacturing the magnetic memory device of the first embodiment;

FIG. 26 schematically shows a part of the process of manufacturing the magnetic memory device of the first embodiment;

FIG. 27 schematically shows a part of the process of manufacturing the magnetic memory device of the first embodiment;

FIG. 28 is a schematic view showing a state of a movable member during a read operation in a first modification of the first embodiment;

FIG. 29 is a schematic view showing another state of a movable member during the read operation in the first modification of the first embodiment;

FIG. 30 is a schematic view showing a state of a movable member during a write operation in the first modification of the first embodiment;

FIG. 31 is a schematic view showing another state of a movable member during the write operation in the first modification of the first embodiment;

FIG. 32 is a schematic view showing the structure of a second modification of the first embodiment;

FIG. 33 is a schematic view showing the structure of a magnetic memory device according to a second embodiment;

FIG. 34 is a schematic view showing a state during a read operation in the second embodiment;

FIG. 35 is a schematic view showing another state during the read operation in the second embodiment;

FIG. 36 is a schematic view showing a state during a write operation in the second embodiment;

FIG. 37 is a schematic view showing a state during the write operation in the second embodiment;

FIG. 38 is a schematic view showing the structure of a magnetic memory device according to a third embodiment;

FIG. 39 is a schematic view showing a state during a read operation in the third embodiment;

FIG. 40 is a schematic view showing another state during the read operation in the third embodiment;

FIG. 41 is a schematic view showing a state during a write operation in the third embodiment;

FIG. 42 is a schematic view showing a state during the write operation in the third embodiment;

FIG. 43 is a schematic view showing the structure of a magnetic memory device according to a modification of the first embodiment;

FIG. 44 is a schematic view showing the structure of a magnetic memory device according to a modification of the second embodiment; and

FIG. 45 is a schematic view showing the structure of a magnetic memory device according to a modification of the third embodiment.

### DETAILED DESCRIPTION

In general, according to one embodiment, a magnetic memory device includes: a first electrode; a second electrode having magnetism and having a major surface facing a major surface of the first electrode;

a third electrode having a major surface facing the major surface of the first electrode and located away from the second electrode; and a movable member having magnetism and located between the first and second electrodes and between the first and third electrodes, the movable member being able to be brought into contact with the first electrode and being able to be selectively brought into contact with one of the second and third electrodes.

### First Embodiment

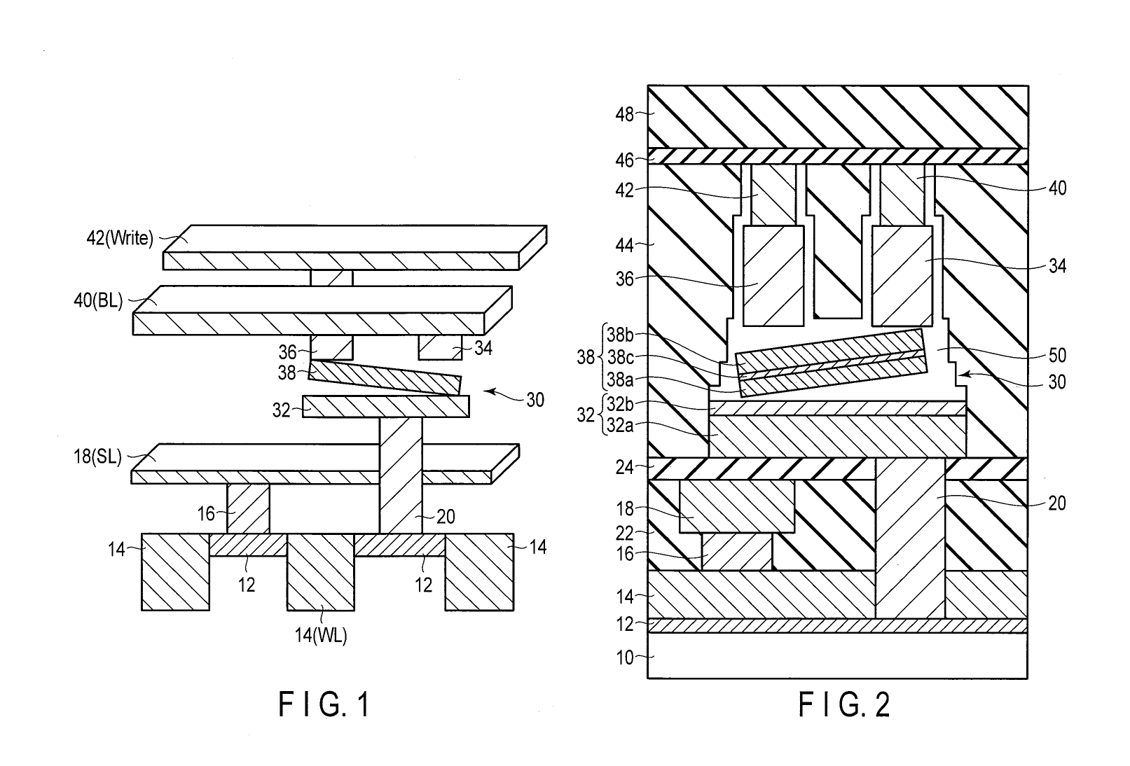

FIG. 1 is a schematic view showing the structure of a magnetic memory device according to the first embodiment. FIG. 2 is a schematic view showing, in more detail, the structure of the magnetic memory device according to the first embodiment.

A MOS transistor as a select transistor is formed on a semiconductor substrate (silicon substrate) 10. More specifically, source/drain regions 12 are formed in a surface portion of the semiconductor substrate 10, and a gate insulating film (not shown) and a gate electrode are formed on the semiconductor substrate 10. The gate electrode constitutes a word line 14.

One of the source and drain regions is connected to a source line 18 via a contact portion 16. The other of the source and drain regions is connected to a contact portion 20. The contact portion 16, the source line 18 and the contact portion 20 are surrounded by an interlayer insulating film 22. A barrier insulating film 24 is formed on the interlayer insulating film 22.

A magnetic element 30 is provided on the barrier insulating film 24. The magnetic element 30 has a lower electrode (first electrode) 32, an upper electrode (second electrode) 34 having magnetism and electrical conductivity, and having a major surface facing the major surface of the lower electrode 32, an upper electrode (third electrode) 36 having magnetism and electrical conductivity, having a major surface facing the major surface of the lower electrode 32, and located away from the upper electrode 34, and a movable member 38 interposed between the lower and upper electrodes 32 and 34 and between the lower and upper electrodes 32 and 36. In the first embodiment, the lower electrode 32 is formed of a lower portion 32a and an upper portion 32b. The lower portion 32a is formed of a metal film, and the upper portion 32b is formed of a noble metal film. The upper electrodes 34 and 36 also serve as contacts.

The movable member 38 is a magnetic member, can be brought into contact with the lower electrode 32, and can be selectively brought into contact with one or the other of the upper electrodes 34 and 36. Further, the movable member 38 has perpendicular magnetization. The movable member 38 comprises a lower magnetic layer (first magnetic layer) 38a having fixed magnetization, an upper magnetic layer (second magnetic layer) 38b having variable magnetization and being able to be selectively brought into contact with one or the other of the upper electrodes 34 and 36, and a nonmagnetic layer 38c interposed between the lower and upper magnetic layers 38a and 38b. The lower magnetic layer 38a is a fixed layer (pin layer), and the upper magnetic layer 38b is a free layer. The lower and upper magnetic layers 38a and 38b are magnetic layers (ferromagnetic layers) having electrical conductivity, and the nonmagnetic layer 38c is a nonmagnetic layer having electrical conductivity. If the coercive force of the lower magnetic layer 38a is set greater than that of the upper magnetic layer 38b, the magnetization of the upper magnetic layer 38b can be fixed. To this end, the lower magnetic layer 38a is made thick.

Since the magnetization of the upper magnetic layer 38b is variable, the magnetic pole (N or S) on the side of the major surface of the movable member 38 (facing the upper electrodes 34 and 36) is variable.

Specifically, the magnetic pole of the upper magnetic layer 38b is variable in accordance with the direction of a write current flowing through the movable member 38. In more detail, the magnetization of the upper magnetic layer 38b becomes parallel or antiparallel relative to the fixed magnetization of the lower magnetic layer 38a in accordance with the direction of the write current flowing through the movable member 38.

The major-surface-side magnetic poles of the upper electrodes 34 and 36 differ from each other. Namely, one of the upper electrodes 34 and 36 is the N pole, and the other is the S pole. The upper electrodes 34 and 36 are formed of a ferromagnetic material containing at least one of nickel (Ni), iron (Fe) and cobalt (Co).

A bit line 40 is connected to the upper electrode 34, and a write line 42 is connected to the upper electrode 36.

The magnetic element 30, the bit line 40 and the write line 42 are surrounded by an interlayer insulating film 44. A barrier insulating film 46 is formed on the interlayer insulating film 44, and an interlayer insulating film 48 is formed on the barrier insulating film 46.

The movable member 38 is surrounded by a space 50 defined between the interlayer insulating film 44 and the movable member 38. In the example shown in FIG. 2, the space 50 surrounds the movable member 38, the upper electrodes 34 and 36, the bit line 40 and the write line 42.

As described above, since the movable member 38 is surrounded by the space 50, it is movable. However, the movable member 38 is magnetic, and hence in a normal state, the lower magnetic layer 38a is in contact with the lower electrode 32 and the upper magnetic layer 38b is in contact with one of the upper electrodes 34 and 36. More specifically, in accordance with the magnetic pole of the upper magnetic layer 38b, the upper magnetic layer 38b selectively contacts one or the other of the upper electrodes 34 and 36. Namely, in accordance with the magnetic pole of the upper magnetic layer 38b, the movable member 38 is selectively coupled to one or the other of the bit line 40 and the write line 42. Therefore, the case where the movable member 38 is connected to the bit line 40, and the case where the movable member 38 is connected to the write line 42 can be associated with binary information (0 or 1). Thus, the magnetic element 30 can store binary information.

Further, the magnetic element 30 of the first embodiment functions as a three-terminal element. Namely, the lower electrode (first electrode) 32 corresponds to a first terminal, the upper electrode (second electrode) 34 corresponds to a second terminal, and the upper electrode (third electrode) 36 corresponds to a third terminal.

The operation of the magnetic memory device of the first embodiment will be described.

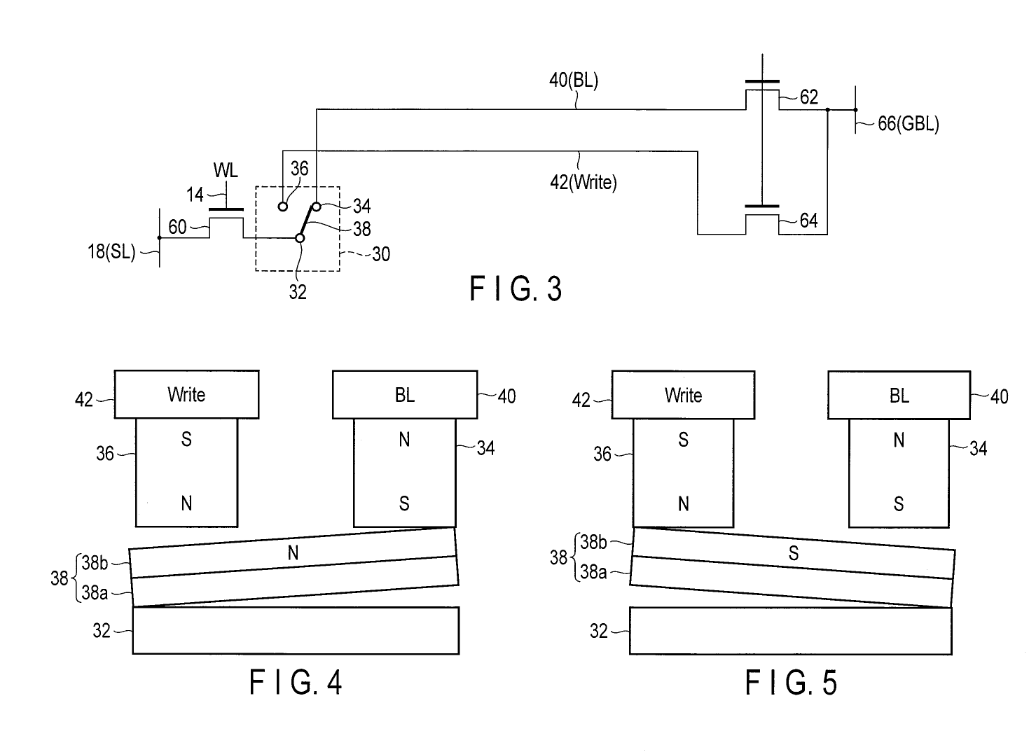

FIG. 3 is a circuit diagram for explaining the principle of the magnetic memory device of the first embodiment. Based on the circuit of FIG. 3, the magnetic memory device can perform a read operation and a write operation. Referring now to FIGS. 1, 2 and 3, these operations will be described.

As already explained, the magnetic element 30 of the first embodiment functions as a three-terminal element having the lower electrode 32 and the upper electrodes 34 and 36. The lower electrode 32 is electrically connectable to the source line (SL; first line) 18 via a select transistor 60. The upper electrode 34 is electrically connectable to the bit line (BL; second line) 40. In the first embodiment, the upper electrode 34 is directly connected to the bit line 40. The upper electrode 36 is electrically connectable to the write line (Write; third line) 42. In the first embodiment, the upper electrode 36 is directly connected to the write line 42.

The select transistor 60 is connected to the word line 14. When an ON signal is applied to the word line 14, the select transistor 60 is turned on, whereby the magnetic element 30 is electrically connected to the source line 18. Further, the magnetic element 30 is connected to a column select transistor 62 via the bit line 40. When the column select transistor 62 is turned on, the magnetic element 30 is electrically connected to a global bit line (GBL) 66 via the column select transistor 62.

The write line 42 is connected to a high-threshold transistor 64 as a switching element. The threshold of the high-threshold transistor 64 is set higher than that of the column select transistor 62. The gates of the column select transistor 62 and the high-threshold transistor 64 are controlled by the same control signal (column select signal). When the column select transistor 62 and the high-threshold transistor 64 are turned on, the write line 42 and the bit line 40 are electrically connected to each other via the high-threshold transistor 64 and the column select transistor 62.

Firstly, the read operation will be described. FIGS. 4 and 5 schematically show the states of the movable member 38 during the read operation. In the examples of FIGS. 4 and 5, it is supposed that the magnetic pole of the major surface of the upper electrode 34 is the S pole, and the magnetic pole of the major surface of the upper electrode 36 is the N pole. During the read operation, the column select transistor 62 is in the ON state and the high-threshold transistor 64 is in the OFF state, since the column select signal is at low voltage.

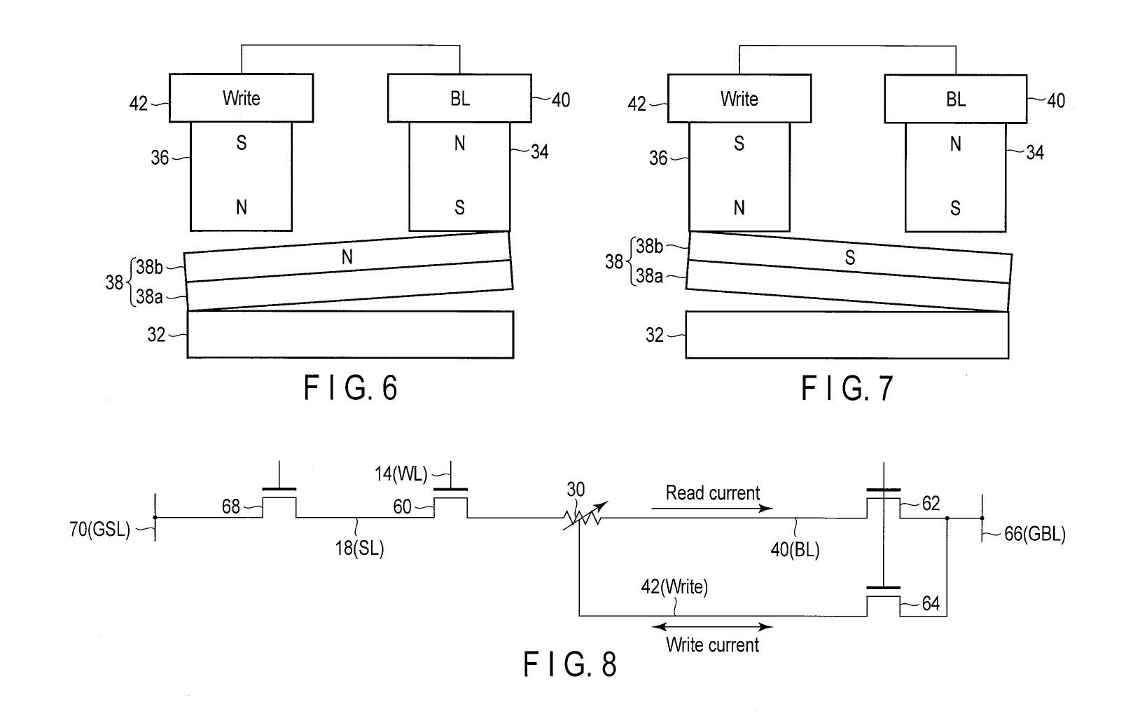

FIG. 4 show a state in which the magnetic pole of the major surface of the movable member 38 (i.e., the major surface of the upper magnetic layer 38b) is the N pole. FIG. 5 show a state in which the magnetic pole of the major surface of the movable member 38 (i.e., the major surface of the upper magnetic layer 38b) is the S pole. Although FIGS. 4 and 5 do not show the nonmagnetic layer 38c of the movable member 38, the nonmagnetic layer 38c is actually provided between the lower and upper magnetic layers 38a and 38b, as in the structure of FIG. 2. The same can be said of FIGS. 6 and 7 showing the write operation.

In the case of FIG. 4, an attractive force is exerted between the movable member 38 and the upper electrode 34, and a repulsive force is exerted between the movable member 38 and the upper electrode 36. As a result, one end of the movable member 38 is brought into contact with the upper electrode 34, and the other end of the movable member 38 is brought into contact with the lower electrode 32, whereby the lower electrode 32, the movable member 38 and the upper electrode 34 form a current route to realize a low resistance state between the bit line (BL) 40 and the source line (SL) 18.

In contrast, in the case of FIG. 5, a repulsive force is exerted between the movable member 38 and the upper electrode 34, and an attractive force is exerted between the movable member 38 and the upper electrode 36. As a result, the above-mentioned one end of the movable member 38 is brought into contact with the lower electrode 32, and the above-mentioned other end of the movable member 38 is brought into contact with the upper electrode 36, whereby the lower electrode 32, the movable member 38 and the upper electrode 36 form a current route. During the read operation, however, the high-threshold transistor 64 is in the OFF state. Accordingly, a high resistance state is realized between the bit line (BL) 40 and the source line (SL) 18.

As can be understood from the above, when the movable member 38 is in contact with the upper electrode 34, a low resistance state is realized between the bit line (BL) 40 and the source line (SL) 18, while when the movable member 38 is in contact with the upper electrode 36, a high resistance state is realized between the bit line (BL) 40 and the source line (SL) 18. Therefore, the information (0 or 1) stored in the magnetic element 30 can be determined by detecting the resistance between the bit line (BL) 40 and the source line (SL) 18.

Secondly, the write operation will be described. FIGS. 6 and 7 schematically show the states of the movable member 38 during the write operation. During the write operation, the column select transistor 62 is in the ON state and the high-threshold transistor 64 is also in the ON state, since the column select signal is at high voltage.

As described above, during the write operation, the column select transistor 62 and the high-threshold transistor 64 are both in the ON state. Accordingly, the bit line (BL) 40 and the source line (SL) 18 are substantially short-circuited. Thus, writing can be performed on the movable member 38 regardless of whether the movable member 38 is in contact with the upper electrode 34 as shown in FIG. 6, or whether the movable member 38 is in contact with the upper electrode 36 as shown in FIG. 7.

After writing is performed on the movable member 38, the magnetic pole of the major surface of the movable member 38 may change from the N pole to the S pole, or from the S pole to the N pole. In this case, the movable member 38 will change from the state of FIG. 6 to that of FIG. 7, or from the state of FIG. 7 to that of FIG. 6, and then it is stabilized in the changed state. Therefore, even in this case, appropriate writing can be performed on the movable member 38.

As described above, in the magnetic memory device of the first embodiment, the movable member 38 having magnetism can be selectively brought into contact with one or the other of the upper electrodes 34 and 36. This enables the case where the movable member 38 is in contact with the upper electrode 34, and the case where the movable member 38 is in contact with the upper electrode 36, to be associated with binary information (0 or 1). Thus, the embodiment can provide a new magnetic memory device wherein the magnetic element 30 can store binary information.

Further, in the magnetic memory device of the embodiment, the movable member 38 comprises the lower magnetic layer 38a, the upper magnetic layer 38b, and the nonmagnetic layer 38c interposed therebetween. Namely, such an insulating layer as the tunnel barrier layer employed in the conventional magnetic elements does not exist between the lower and upper magnetic layers 38a and 38b. This significantly reduces the resistance of the movable member 38 itself. If, for example, the case where the movable member 38 is in contact with the upper electrode 34 is set as a low resistance state, and the case where the movable member 38 is in contact with the upper electrode 36 is set as a high resistance state, the resistance in the low resistance state can be set to a low value that is substantially determined only from the parasitic resistance.

Thus, when a read operation is performed, the level of a read signal (e.g., the level of a read current) in the low resistance state can be increased, whereby a reliable read operation can be realized. For instance, in the low resistance state wherein the movable member 38 is in contact with the upper electrode 34, the resistance of the movable member 38 is 10 Ω, and the parasitic resistance is about 10 kΩ. In contrast, in the high resistance state wherein the movable member 38 is in contact with the upper electrode 36, the resistance is not less than 1 gigaohm.

When a write operation is performed, it is performed on the movable member 38 that is set at a very low resistance value, with the result that a sufficient write current can be secured. Also in this case, the resistance of the movable member 38 is 10 Ω and the parasitic resistance is about 10 kΩ as mentioned above, which enables sufficient write current to be secured.

Further, the magnetic element of the embodiment does not have to use an insulating film, such as a tunnel barrier film, whose reliability is hard to secure, and therefore can enhance its reliability.

A description will now be given of a specific circuit structure example of the magnetic memory device of the embodiment.

FIG. 8 is a circuit diagram showing a first circuit structure example of the magnetic memory device of the first embodiment.

The circuit of FIG. 8 is similar in basic structure to that of FIG. 3. More specifically, the circuit of FIG. 8 comprises a word line 14, a source line 18, a bit line 40, a write line 42, a magnetic element 30, a select transistor 60, a column select transistor 62, a high-threshold transistor 64, a column select transistor 68, a global bit line 66 and a global source line 70.

During a read operation, the select transistor 60, the column select transistor 62 and the column select transistor 68 are in the ON state. Further, during the read operation, a low voltage is applied to the column select transistor 62, and hence the high-threshold transistor 64 is in the OFF state. Accordingly, when the movable member 38 in the magnetic element 30 is connected to the bit line 40 side, data indicating a low resistance state is read. In contrast, when the movable member 38 in the magnetic element 30 is connected to the write line 42 side, a high resistance state is read.

Also during a write operation, the select transistor 60, the column select transistor 62 and the column select transistor 68 are in the ON state. Further, during the write operation, a high voltage is applied to the column select transistor 62, and hence the high-threshold transistor 64 is in the ON state, and the bit line 40 and the write line 42 are electrically short-circuited. Accordingly, regardless of whether the movable member 38 is in contact with the upper electrode 34 as shown in FIG. 6, or whether the movable member 38 is in contact with the upper electrode 36 as shown in FIG. 7, appropriate writing can be performed.

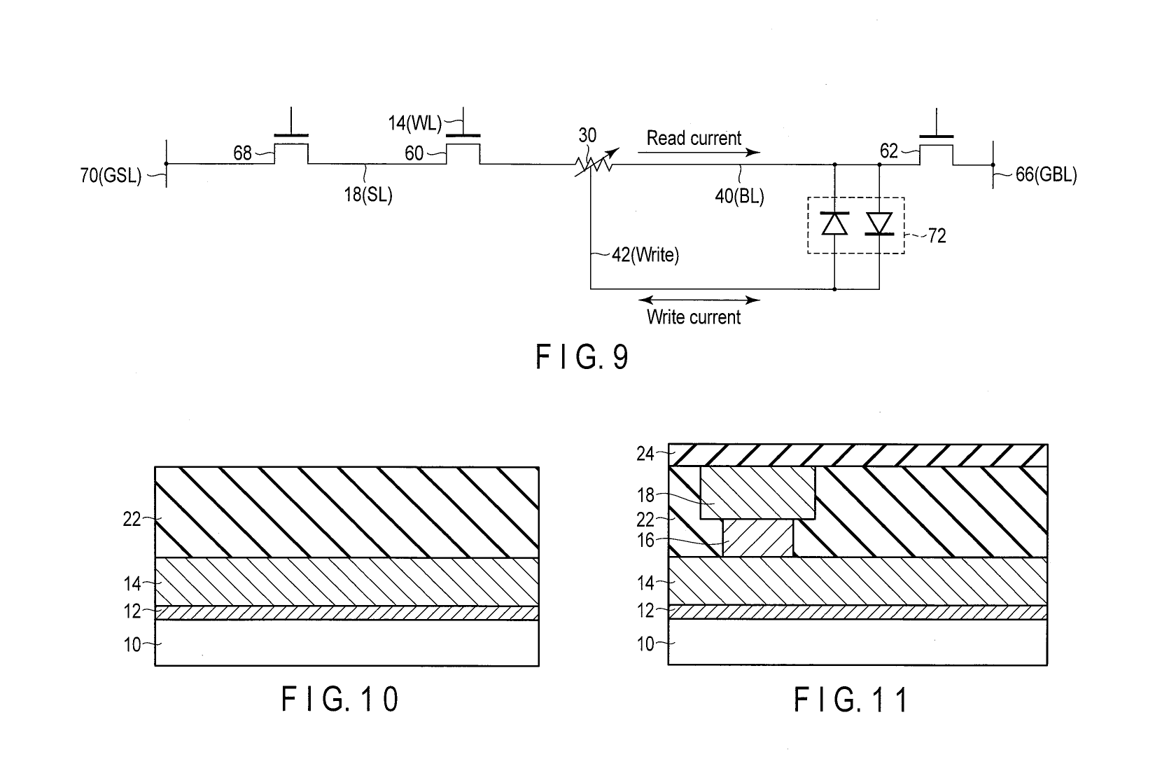

FIG. 9 is a circuit diagram showing a second circuit structure example of the magnetic memory device of the first embodiment.

The basic circuit structure and operation of the circuit shown in FIG. 9 are similar to those shown in

FIGS. 3 and 8. In the example of FIG. 9, however, a bidirectional diode 72 is employed as a switching element, instead of the high-threshold transistor 64. The bidirectional diode 72 may be a single element or be a structure wherein two diodes are connected in parallel.

Since the read operation is performed with a low voltage, the bidirectional diode 72 is in the OFF state (nonconductive state) during the read operation. Accordingly, substantially the same operation as that performed when the high-threshold transistor 64 is in the OFF state shown in FIGS. 3 and 8 is performed. Namely, during the read operation, data indicating one of the low resistance state and the high resistance state is read in accordance with the state of the movable member 38 in the magnetic element 30. In contrast, the write operation is performed with a high voltage, and hence the bidirectional diode 72 is in the ON state (conductive state). Accordingly, substantially the same operation as that performed when the high-threshold transistor 64 is in the ON state shown in FIGS. 3 and 8 is performed, thereby performing writing to the movable member 38 in the magnetic element 30.

As described above, since the first embodiment employs switching elements (the high-threshold transistor 64 and the bidirectional diode 72), reading and writing can be performed with a simple circuit structure.

FIGS. 10 to 27 schematically show a process of manufacturing the magnetic memory device of the first embodiment. Referring now to FIGS. 10 to 27, the process of manufacturing the magnetic memory device of the first embodiment will be described.

Firstly, as shown in FIG. 10, an element isolation region (not shown) is formed in the semiconductor substrate (silicon substrate) 10. Subsequently, a_{g}ate insulating film (not shown) and a gate electrode are formed on the semiconductor substrate 10. The gate electrode serves as the word line 14. Further, a source/drain region 12 is formed in the semiconductor substrate 10. After that, the interlayer insulating film 22 is formed on the entire surface of the resultant structure. The interlayer insulating film 22 may be formed of BPSG or P-TEOS. The upper surface of the interlayer insulating film 22 is flattened.

Thereafter, as shown in FIG. 11, a contact hole and a wiring groove are formed, and then the contact portion 16 and the source line 18 are formed by filling the contact hole and the wiring groove with a metal film. The contact portion 16 and the source line 18 may be formed of tungsten (W), titanium nitride (TiN), copper (Cu), etc. Subsequently, the barrier insulating film 24 is formed on the interlayer insulating film 22 and the source line 18. The barrier insulating film 24 may be formed of silicon nitride (SiN).

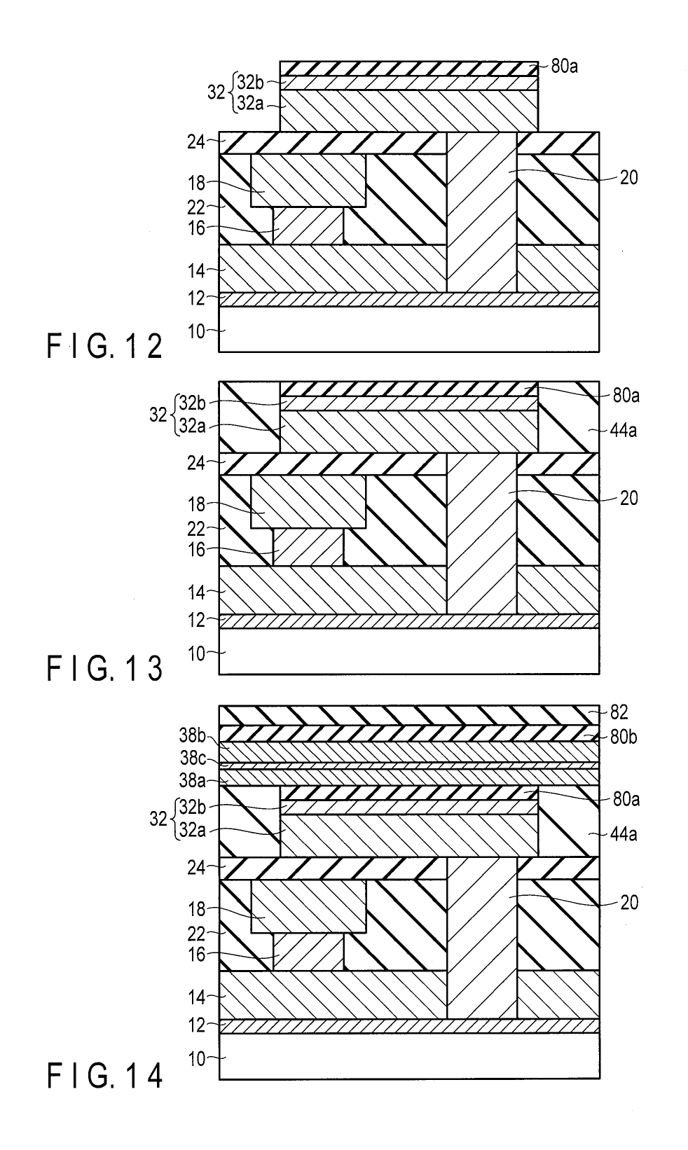

As shown in FIG. 12, the contact portion 20 connected to the source/drain region 12 is formed in the barrier insulating film 24 and the interlayer insulating film 22. After that, the lower electrode film 32 is formed on the barrier insulating film 24 and the contact portion 20. The lower electrode film 32 may be formed of tantalum (Ta), ruthenium (Ru), iridium (Ir), platinum (Pt), tungsten (W), copper (Cu), titanium nitride (TiN), etc. In the first embodiment, the lower electrode film 32 comprises the lower layer 32a and an upper layer 32b. In this case, it is preferable that the upper layer 32b be formed of a noble metal. The use of the noble metal film can realize a stable contact resistance. Subsequently, a sacrifice layer 80a is formed on the lower electrode film 32. The sacrifice layer 80a may be formed of polysilicon, a Low-k material, silicon nitride (SiN), carbon, an organic resin, etc. Further, the lower electrode film 32 and the sacrifice layer 80a are processed into a pattern.

As shown in FIG. 13, an interlayer insulating film 44a is formed on the entire surface of the resultant structure, and is then flattened.

As shown in FIG. 14, a stacked film of the lower magnetic layer 38a, the nonmagnetic layer 38c and the upper magnetic layer 38b as a film for the movable member is provided on the interlayer insulating film 44a and the sacrifice layer 80a. Both the lower magnetic layer 38a and the upper magnetic layer 38b are ferromagnetic layers having electrical conductivity. The lower magnetic layer 38a is a fixed layer having fixed magnetization, and the upper magnetic layer 38b is a free layer having variable magnetization. The stacked film of the lower magnetic layer 38a, the nonmagnetic layer 38c and the upper magnetic layer 38b has a spin valve structure, and has a structure called a Current Perpendicular to Plane (CCP)-GMR structure. A sacrifice layer 80b is formed on the upper magnetic layer 38b. The sacrifice layer 80b may be formed of the same material as that of the sacrifice layer 80a. A hard mask film 82 is formed on the sacrifice layer 80b.

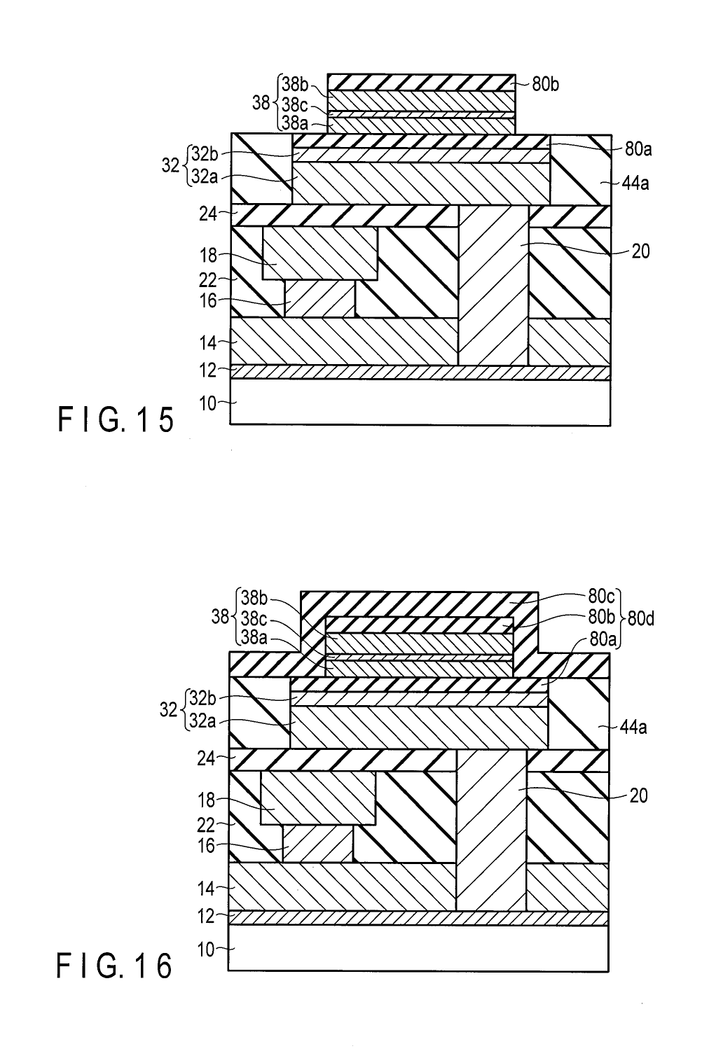

Subsequently, as shown in FIG. 15, the hard mask film 82, the upper magnetic layer 38b, the nonmagnetic layer 38c and the lower magnetic layer 38a are patterned. More specifically, a resist pattern (not shown) is provided on the hard mask film 82, and the hard mask film 82 is patterned using the resist pattern as a mask pattern. Using, in turn, the patterned hard mask film 82 as a mask, the upper magnetic layer 38b, the nonmagnetic layer 38c and the lower magnetic layer 38a are patterned, using, for example, Reactive Ion Etching (RIE) or Ion Beam Etching (IBE). As a result, the movable member 38, which comprises the upper magnetic layer 38b, the lower magnetic layer 38a and the nonmagnetic layer 38c, is obtained.

Thereafter, as shown in FIG. 16, a sacrifice layer 80c is formed on the entire surface of the resultant structure. The sacrifice layer 80c may be formed of the same material as that of the sacrifice layers 80a and 80b. As a result, a structure in which the movable member 38 is surrounded by a sacrifice layer 80d (=the sacrifice layers 80a, 80b and 80c) is obtained.

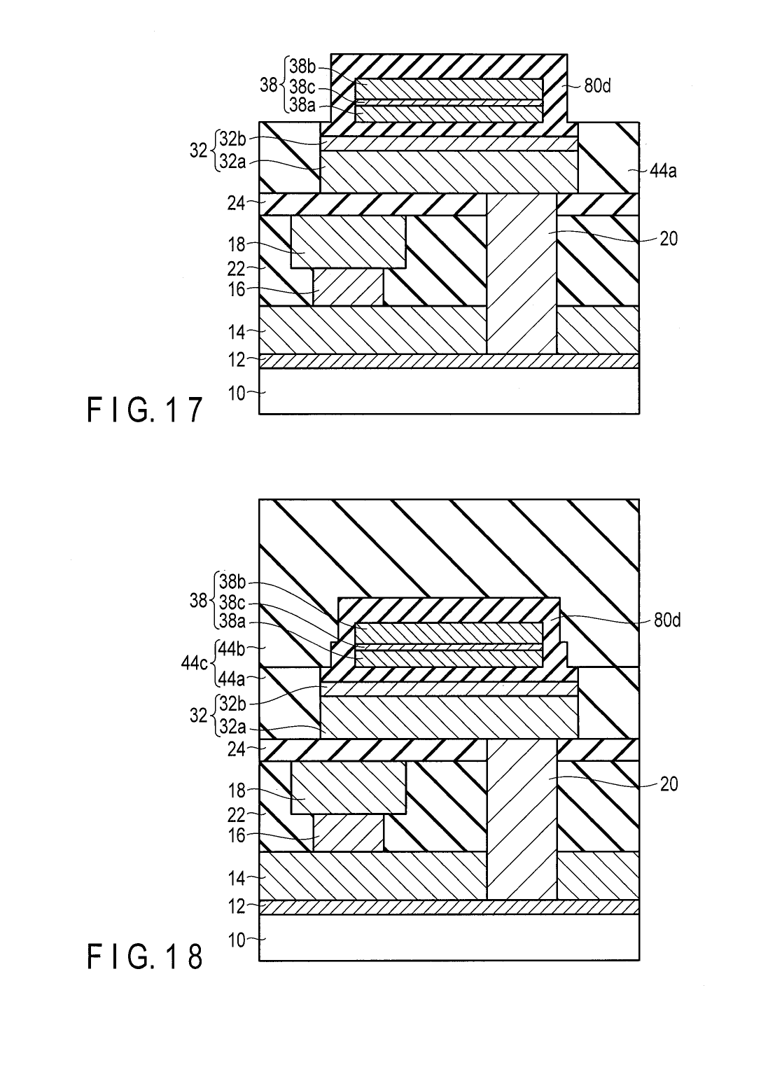

As shown in FIG. 17, the sacrifice layer 80d is etched back, whereby the portion of the sacrifice layer 80d on the interlayer insulating film 44a is removed. As shown in FIG. 18, an interlayer insulating film 44b is formed on the entire surface of the resultant structure and is flattened, whereby a structure in which the sacrifice layer 80d is surrounded by an interlayer insulating film 44c (=the interlayer insulating films 44a and 44b) is obtained.

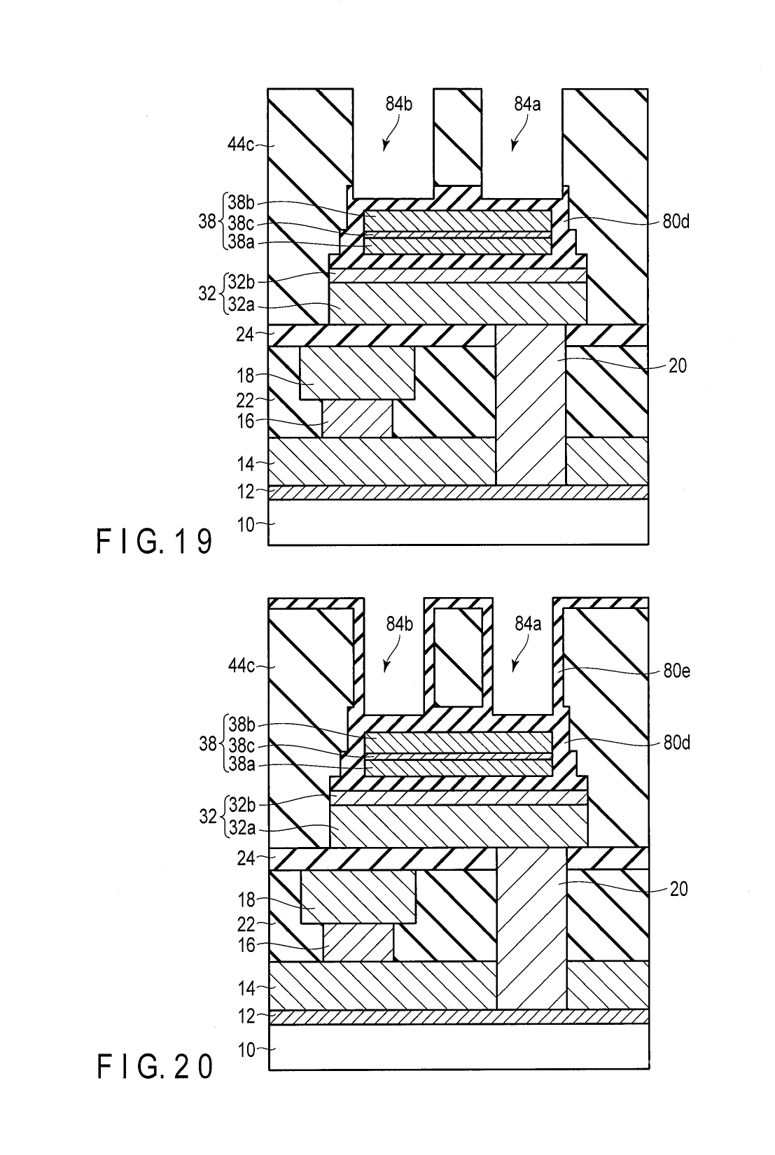

As shown in FIG. 19, contact holes 84a and 84b are formed in the interlayer insulating film 44c.

As shown in FIG. 20, a sacrifice layer 80e is formed on the entire surface of the resultant structure. The sacrifice layer 80e may be formed of the same material as that of the sacrifice layers 80a, 80b and 80c.

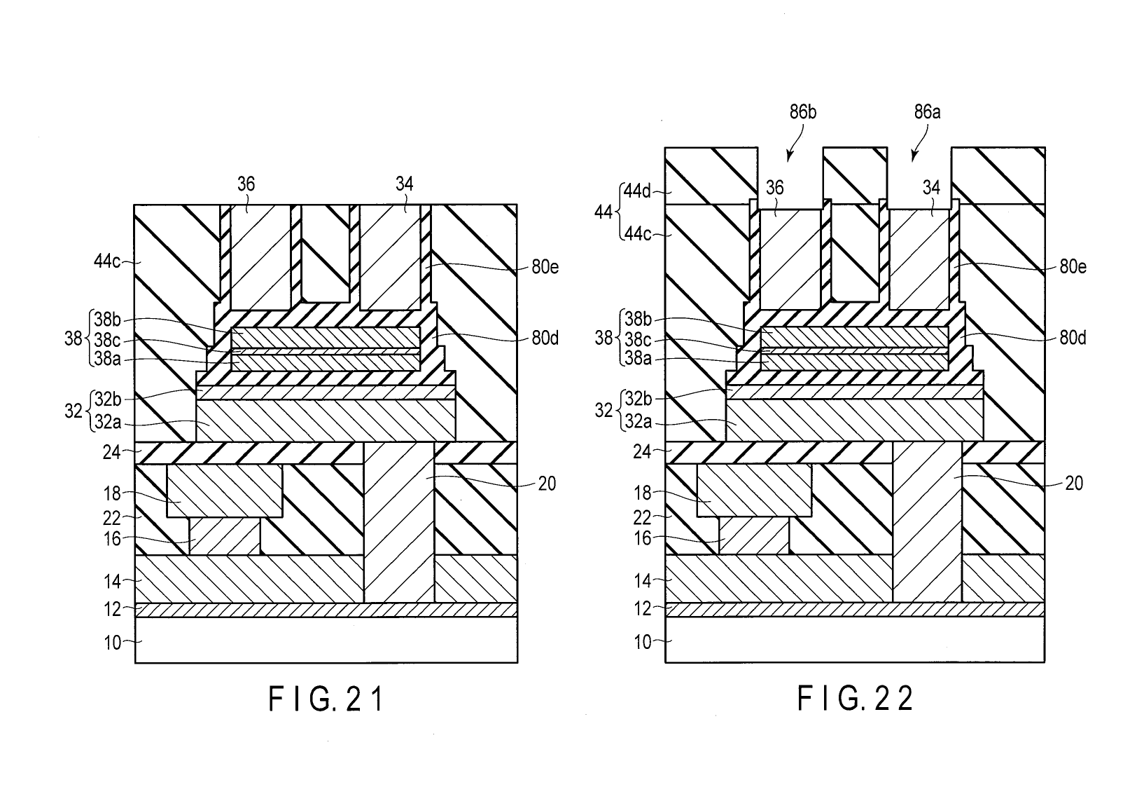

As shown in FIG. 21, contact plugs that will serve as the upper electrodes 34 and 36 are formed in the contact holes 84a and 84b. More specifically, an upper electrode film is formed on the entire surface of the resultant structure and is flattened. The upper electrodes 34 and 36 are formed of a ferromagnetic material containing at least one of nickel (Ni), iron (Fe) and cobalt (Co).

As shown in FIG. 22, an interlayer insulating film 44d is formed on the entire surface of the resultant structure. The interlayer insulating film 44d and the interlayer insulating film 44c serve as an interlayer insulating film 44 as a whole. Subsequently, wiring grooves for the bit line and write line are formed in the interlayer insulating film 44.

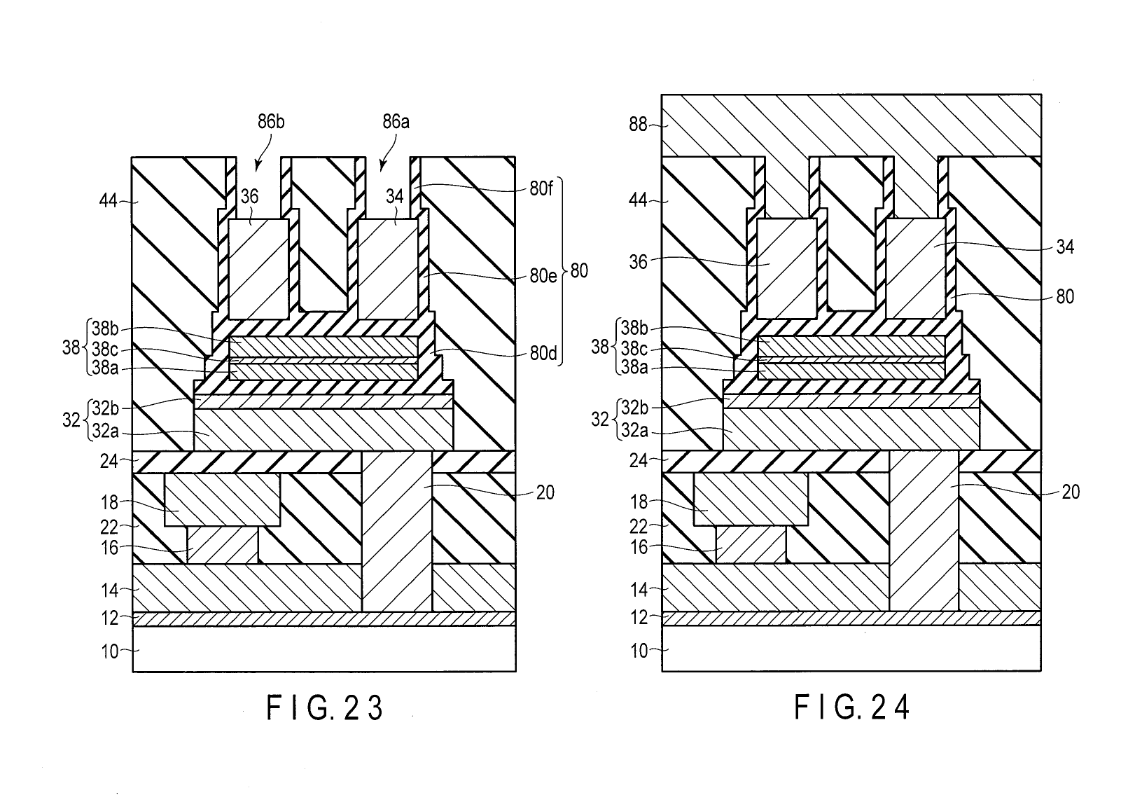

As shown in FIG. 23, a sacrifice film 80f is formed on the entire surface of the resultant structure, and is processed to be left only on the side walls of the wiring grooves. Further, the sacrifice films 80d, 80e and 80f are formed continuously to serve as a sacrifice film 80.

As shown in FIG. 24, a metal film 88 for the bit line and write line is formed on the entire surface of the resultant structure. The metal film 88 is formed of copper (Cu) or tungsten (W).

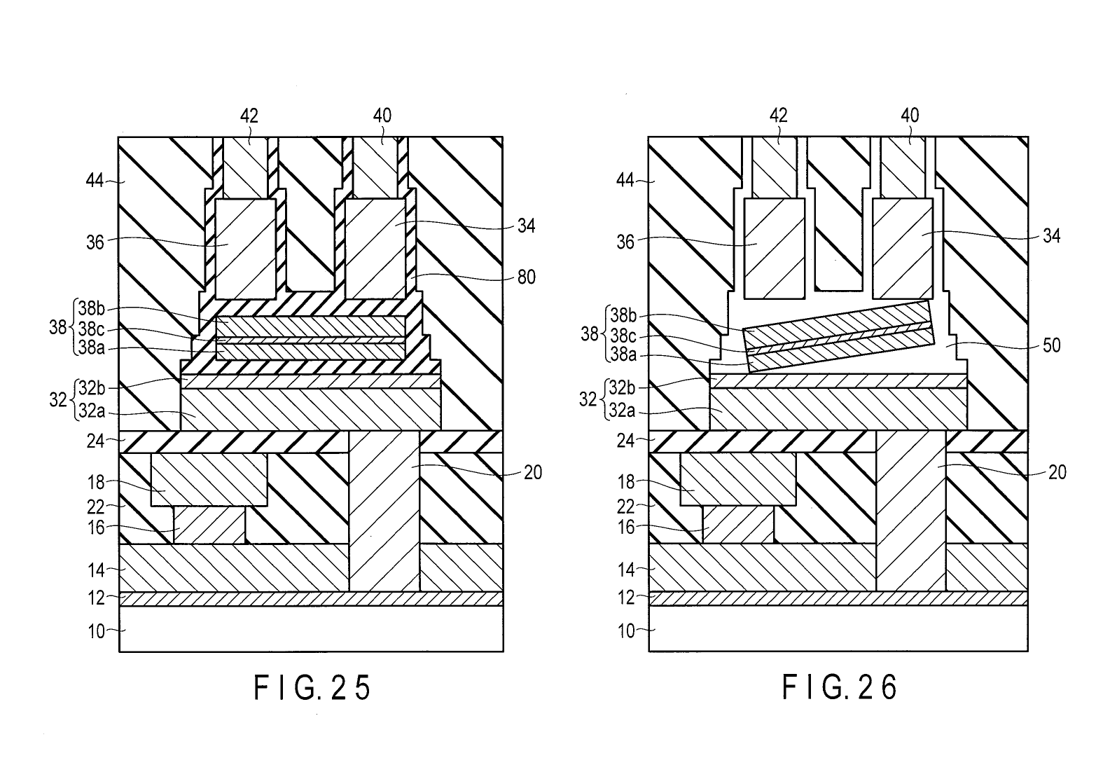

As shown in FIG. 25, the metal film 88 is flattened to form the bit line 40 and the write line 42.

As shown in FIG. 26, the sacrifice film 80 is removed. As a result, the movable member 38 is separated from the ambient films and becomes movable. If the sacrifice film 80 is formed of carbon or an organic material, it is removed using oxygen plasma. If the sacrifice film 80 is formed of silicon nitride (SiN), it is removed using phosphoric acid. If the sacrifice film 80 is formed of polysilicon, it is removed using XeF₂ gas. If the sacrifice film 80 is formed of a Low-k material, it is removed using HF vapor or HF solution.

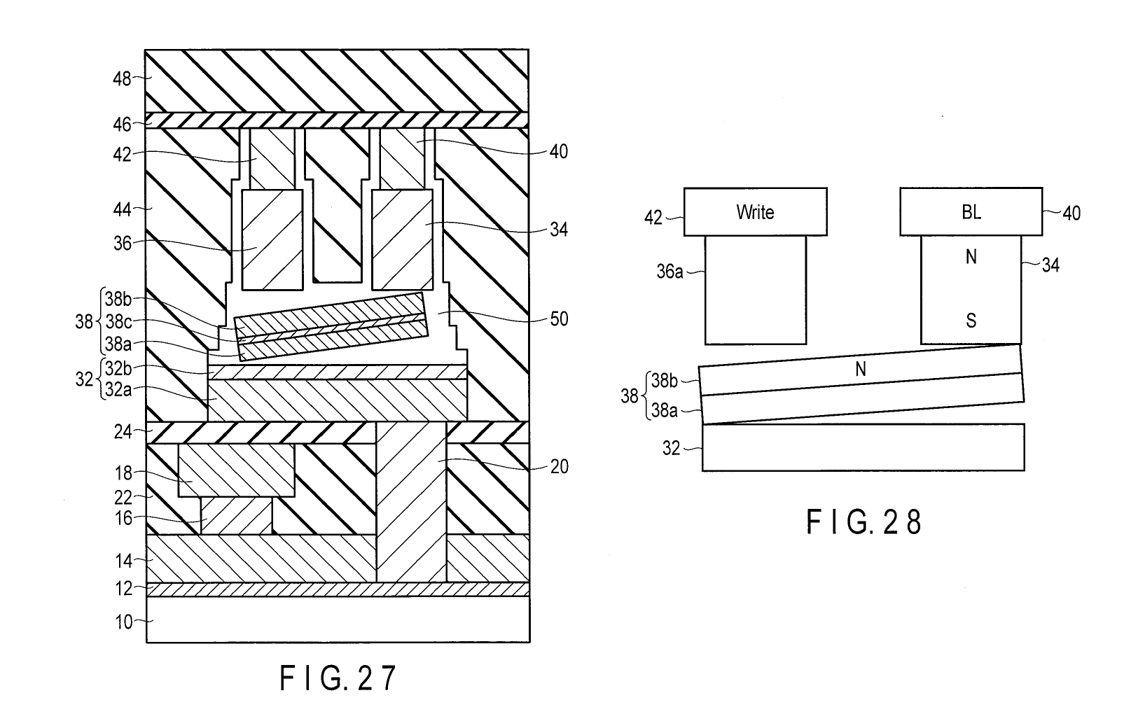

As shown in FIG. 27, a barrier insulating film 46 is formed on the entire surface of the resultant structure, and an interlayer insulating film 48 is formed on the barrier insulating film 46.

As described above, by forming the sacrifice film 80 around the movable member 38 and then removing the sacrifice film 80, the movability of the movable member 38 is secured.

A first modification of the first embodiment will now be described.

Although in the first embodiment, both upper electrodes 34 and 36 are formed of a magnetic material, one of the upper electrodes 34 and 36 may be formed of a nonmagnetic material. More specifically, the upper electrode 34 is formed of a magnetic material, and the upper electrode 36 is formed of a nonmagnetic material, such as tungsten (W) or copper (Cu).

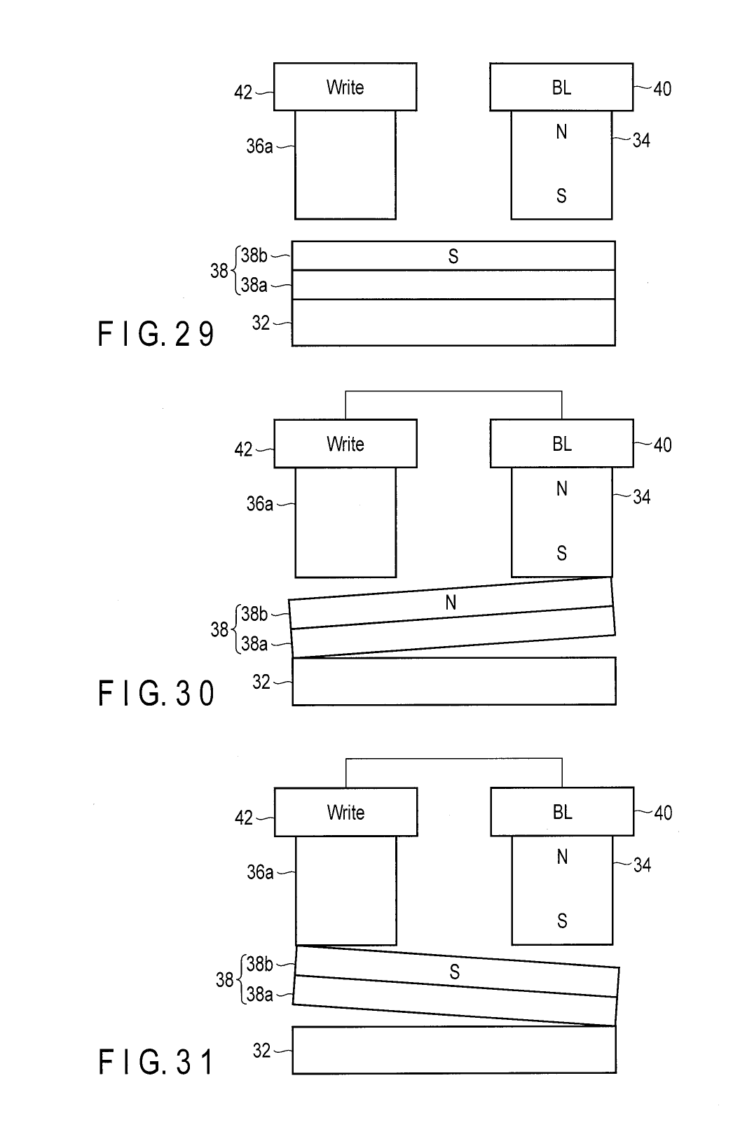

FIGS. 28 and 29 schematically show the states of the movable member 38 during a read operation. FIG. 28 shows a case where the magnetic pole of the major surface of the movable member 38 (i.e., the major surface of the upper magnetic layer) is the N pole. FIG. 29 shows a case where the magnetic pole of the major surface of the movable member 38 (i.e., the major surface of the upper magnetic layer) is the S pole. Although FIGS. 28 and 29 do not show the nonmagnetic layer of the movable member 38, the nonmagnetic layer 38c is actually provided between the lower and upper magnetic layers 38a and 38b, as in the structure of FIG. 2. The same can be said of FIGS. 30 and 31 showing a write operation.

In the case of FIG. 28, an attractive force is exerted between the movable member 38 and the upper electrode 34, and no particular force is exerted between the movable member 38 and an upper electrode 36a. Because of the attractive force between the movable member 38 and the upper electrode 34, one end of the movable member 38 is brought into contact with the upper electrode 34, whereby the lower electrode 32, the movable member 38 and the upper electrode 34 form a current route to realize a low resistance state between the bit line (BL) 40 and the source line (SL, not shown).

In the case of FIG. 29 a repulsive force is exerted between the movable member 38 and the upper electrode 34, and no particular force is exerted between the movable member 38 and an upper electrode 36a. As a result, the movable member 38 is out of contact with either of the upper electrodes 34 and 36a. Accordingly, a high resistance state is realized between the bit line (BL) 40 and the source line (SL, not shown).

FIGS. 30 and 31 schematically show the states of the movable member 38 during the write operation.

As shown in FIG. 30, when the magnetic pole of the major surface of the movable member 38 (i.e., the maⱼor surface of the upper magnetic layer) is the N pole, an attractive force is exerted between the movable member 38 and the upper electrode 34. As a result, one end of the movable member 38 is brought into contact with the upper electrode 34. In contrast, as shown in FIG. 31, when the magnetic pole of the major surface of the movable member 38 (i.e., the major surface of the upper magnetic layer) is the S pole, a repulsive force is exerted between the movable member 38 and the upper electrode 34. As a result, the one end of the movable member 38 is out of contact with the upper electrode 34. However, during the write operation, a relatively high voltage (e.g., about 1V) is applied between the lower electrode 32 and the upper electrode 36a, and hence the other end of the movable member 38 is brought into contact with the upper electrode 36a by an electrostatic force. This means that writing can be performed on the movable member 38 in each of the cases shown in FIGS. 30 and 31.

As is evident from the above, this modification can also provide the same advantage as that of the above-described embodiment.

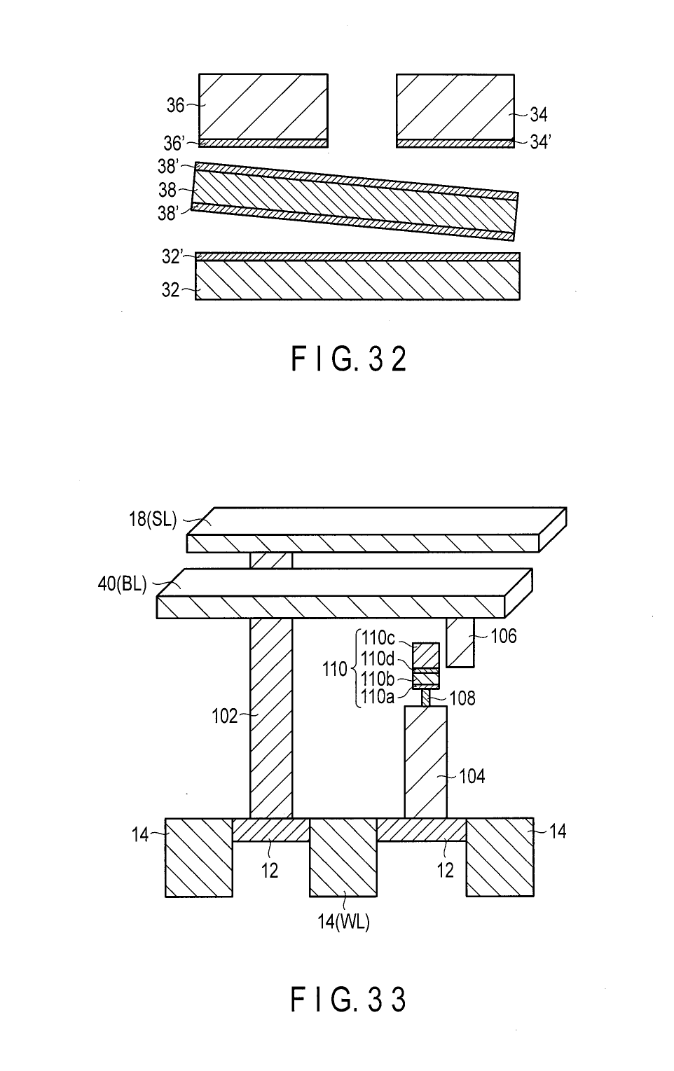

A second modification of the first embodiment will be described. FIG. 32 schematically shows the second modification.

In the second modification, the major surface of the lower electrode 32 is formed of a noble metal film 32′, the major surface of the upper electrode 34 is formed of a noble metal film 34′, the major surface of the upper electrode 36 is formed of a noble metal film 36′, both major surfaces (i.e., the major surface facing the lower electrode 32, and the major surface facing the upper electrodes 34 and 36) of the movable member 38 are formed of noble metal films 38′. This structure can realize a stable contact to reduce the contact resistance. It is preferable that the noble metal films are formed of at least one of platinum (Pt), iridium (Ir), iridium oxide (IrO₂), ruthenium (Ru), gold (Au), palladium (Pd), tungsten (W) and rhodium (Rh).

In general, at least one of the major surfaces of the lower electrode 32 and the upper electrodes 34 and 36, the major surface of the movable member 38 facing the lower electrode 32, and the major surface of the movable member 38 facing the upper electrodes 34 and 36 may be formed of a noble metal.

### Second Embodiment

A second embodiment will be described. The second embodiment is similar in basic structure to the first embodiment. In the second embodiment, the elements similar to those of the first embodiment are not described.

FIG. 33 schematically shows a magnetic memory device according to the second embodiment. In the second embodiment, elements similar to those shown in FIG. 1 are denoted by corresponding reference numbers, and no detailed description will be given thereof.

One of the source/drain regions 12 is connected to the source line 18 via a contact portion 102. The other of the source/drain regions 12 is connected to a contact portion 104. Further, the bit line 40 is connected to a contact portion 106 (first magnetic member) having magnetism and conductivity. The contact portion 106 is fixed. The contact portion 104 is connected to one end of a conductive spring portion 108. The other end of the spring portion 108 is connected to a movable member (second magnetic member) 110.

The movable member 110 is surrounded by a space so that it can move. Further, the movable member 110 has magnetism and can be brought into contact with the contact portion 106. More specifically, the movable member 110 has perpendicular magnetization. The movable member 110 comprises an electrode portion 110a, a lower magnetic layer (first magnetic layer) 110b provided on the electrode portion 110a and having fixed magnetization, an upper magnetic layer (second magnetic layer) 110c having variable magnetization and being able to be brought into contact with the electrode 106, and a nonmagnetic layer 110d interposed between the lower magnetic layer 110b and the upper magnetic layer 110c. The lower magnetic layer 110b is a fixed layer (pin layer), and the upper magnetic layer 110c is a free layer. The lower and upper magnetic layers 110b and 110c are magnetic layers (ferromagnetic layers) having electrical conductivity, and the nonmagnetic layer 110d is a nonmagnetic layer having electrical conductivity.

The magnetization of the upper magnetic layer 110c is variable. Namely, the magnetic pole (the N or S pole) of the portion of the movable member 110 that is brought into contact with the contact portion 106 is variable. Specifically, the magnetic pole of the upper magnetic layer 110c is changed in accordance with the direction of the write current flowing through the movable member 110. In more detail, the magnetization of the upper magnetic layer 110c becomes parallel or antiparallel relative to the fixed magnetization of the lower magnetic layer 110b in accordance with the direction of the write current flowing through the movable member 110.

The magnetic element of the second embodiment comprises the contact portion 106, the spring portion 108 and the movable member 110. The magnetic element is configured to select either a state in which the contact portion 106 and the movable member 110 are separate from each other, or a state in which the contact portion 106 and the movable member 110 are in contact with each other, in accordance with the magnetic force exerted between them. Therefore, in the magnetic element of the second embodiment, the state where the contact portion 106 and the movable member 110 are separate from each other, and the state where the contact portion 106 and the movable member 110 are in contact with each other can be associated with binary information (0 or 1). Thus, the magnetic element can store binary information. Further, the magnetic element of the second embodiment functions as a two-terminal element.

The operation of the magnetic memory device of the second embodiment will be described.

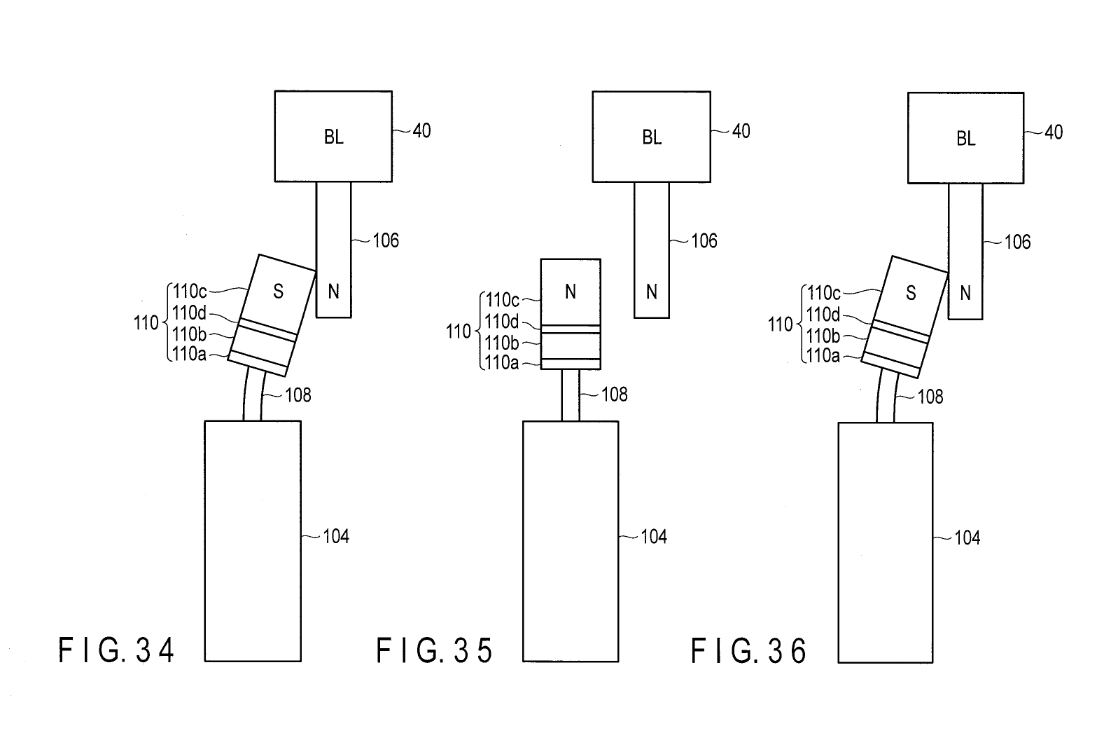

Referring first to FIGS. 34 and 35, the read operation will be described. In FIGS. 34 and 35, the lower end of the contact portion 106 is the N pole. FIG. 34 shows a case where the magnet pole of the upper end of the movable member 110 is the S pole, and FIG. 35 shows a case where the magnet pole of the upper end of the movable member 110 is the N pole.

In the case of FIG. 34, an attractive force is exerted between the movable member 110 and the contact portion 106, whereby the upper end of the movable member 110 is brought into contact with the lower end of the contact portion 106. As a result, the contact portion 104, the spring portion 108, the movable member 110 and the contact portion 106 provide a current route. Further, the select transistor (formed of the word line 14 and the source/drain regions 12) is in the ON state. This realizes a low resistance state between the bit line (BL) 40 and the source line (SL) 18 shown in FIG. 33.

In the case of FIG. 35, a repulsive force is exerted between the movable member 110 and the contact portion 106. As a result, the movable member 110 is out of contact with the contact portion 106. Accordingly, the current route between the contact portion 104 and the contact portion 106 is interrupted to thereby realize a high resistance state between the bit line (BL) 40 and the source line (SL) 18.

As is evident from the above, when the movable member 110 is in contact with the contact portion 106, a low resistance state is realized between the bit line (BL) 40 and the source line (SL) 18, while when the movable member 110 is out of contact with the contact portion 106, a high resistance state is realized between the bit line (BL) 40 and the source line (SL) 18. Consequently, by detecting the resistance between the bit line (BL) 40 and the source line (SL) 18, the information (0 or 1) stored in the magnetic element can be determined.

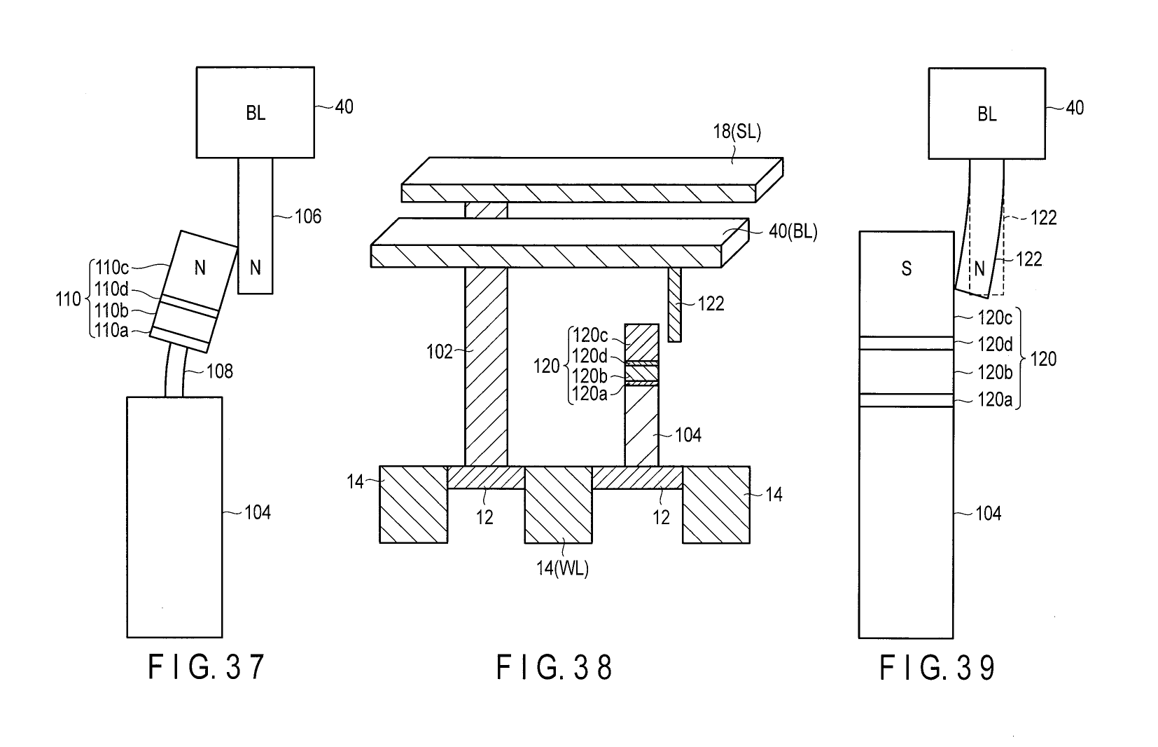

Referring then to FIGS. 36 and 37, the write operation will be described. In FIGS. 36 and 37, the lower end of the contact portion 106 is the N pole.

Further, FIG. 36 shows a case where the magnet pole of the upper end of the movable member 110 is the S pole, and FIG. 37 shows a case where the magnet pole of the upper end of the movable member 110 is the N pole.

In the case of FIG. 36, an attractive force is exerted between the movable member 110 and the contact portion 106, whereby the upper end of the movable member 110 is brought into contact with the lower end of the contact portion 106. In contrast, in the case of FIG. 37, a repulsive force is exerted between the movable member 110 and the contact portion 106. During the write operation, however, a relatively high voltage (e.g., about 1V) is applied between the contact portions 104 and 106. Consequently, an electrostatic force is exerted between the movable member 110 and the contact portion 106. If the electrostatic force (attractive force) exerted between the movable member 110 and the contact portion 106 is set greater than the magnetic force (repulsive force) exerted therebetween, the movable member 110 and the contact portion 106 can be made contact each other. Therefore, writing can be performed on the movable member 110 in both cases of FIGS. 36 and 37.

As described above, in the magnetic memory device of the second embodiment, one or the other of the state in which the contact portion 106 and the movable member 110 are separate from each other, and the state in which these components contact each other can be selected in accordance with the magnetic force exerted between them. Accordingly, in the magnetic element of the second embodiment, the state where the contact portion 106 and the movable member 110 are separate from each other, and the state where the contact portion 106 and the movable member 110 are in contact with each other can be associated with binary information (0 or 1). Thus, the second embodiment can provide a new magnetic memory device capable of storing binary information.

Further, in the magnetic memory device of the second embodiment, an insulating layer, such as a tunnel barrier layer used in the conventional magnetic elements, does not exist between the lower and upper magnetic layers 110b and 110c of the movable member 110. This enables the resistance of the movable member 110 itself to be extremely reduced, and hence enables the resistance assumed in the low resistance state to be reduced.

Therefore, when a read operation is performed, the level of a read signal level (e.g., the level of a read current) in the low resistance state can be increased to thereby realize a reliable read operation.

Also when a write operation is performed, a sufficient write current level can be secured since writing is performed on the movable member 110 that has a very low resistance.

In addition, since the magnetic element of the second embodiment does not have to employ an insulating film, such as a tunnel barrier film, whose reliability is hard to secure, the reliability of the resultant element can be enhanced.

In the second embodiment, a noble metal film may be formed at a portion at which the contact portion 106 and the movable member 110 contact each other, as in the first embodiment.

### Third Embodiment

A third embodiment will be described. The third embodiment is similar in basic structure to the first and second embodiments. In the third embodiment, the elements similar to those of the first and second embodiments are not described.

FIG. 38 schematically shows a magnetic memory device according to the third embodiment. In the third embodiment, elements similar to those shown in FIGS. 1 and 33 are denoted by corresponding reference numbers, and no detailed description will be given thereof.

One of the source/drain regions 12 is connected to the source line 18 via the contact portion 102. The other of the source/drain regions 12 is connected to the contact portion 104. The contact portion 104 is connected to a magnetic member (first magnetic member) 120. The magnetic member 120 is fixed to the contact portion 104.

The magnetic member 120 has magnetism (perpendicular magnetization) and conductivity. The magnetic member 120 comprises an electrode portion 120a, a lower magnetic layer (first magnetic layer) 120b provided on the electrode portion 120a and having fixed magnetization, an upper magnetic layer (second magnetic layer) 120c having variable magnetization and being able to be brought into contact with a movable member 122 described later, and a nonmagnetic layer 120d interposed between the lower and upper magnetic layers 120b and 120c. The lower magnetic layer 120b is a fixed layer (pin layer), and the upper magnetic layer 120c is a free layer. The lower and upper magnetic layers 120b and 120c are magnetic layers (ferromagnetic layers) having electrical conductivity, and the nonmagnetic layer 120d is a nonmagnetic layer having electrical conductivity.

The magnetization of the upper magnetic layer 120c is variable. Specifically, the magnetic pole of the upper magnetic layer 120c is variable in accordance with the direction of a write current flowing through the magnetic member 120. In more detail, the magnetization of the upper magnetic layer 120c becomes parallel or antiparallel relative to the fixed magnetization of the lower magnetic layer 120b in accordance with the direction of the write current flowing through the magnetic member 120.

The bit line 40 is connected to a movable member (second magnetic member) 122 having magnetism and conductivity. The movable member 122 is surrounded by a space and is therefore movable. Specifically, the movable member 122 has elasticity and can be brought into contact with the upper magnetic layer 120c of the magnetic member 120.

The magnetic element of the third embodiment comprises the magnetic member 120 and the movable member 122. The magnetic element is configured to select either a state in which the magnetic member 120 and the movable member 122 are separate from each other, or a state in which the magnetic member 120 and the movable member 122 are in contact with each other, in accordance with the magnetic force exerted between them. Therefore, in the magnetic element of the third embodiment, the state in which the magnetic member 120 and the movable member 122 are separate from each other, and the state in which the magnetic member 120 and the movable member 122 are in contact with each other, can be associated with binary information (0 or 1). Thus, the magnetic element can store binary information. Further, the magnetic element of the third embodiment functions as a two-terminal element.

The operation of the magnetic memory device of the third embodiment will be described.

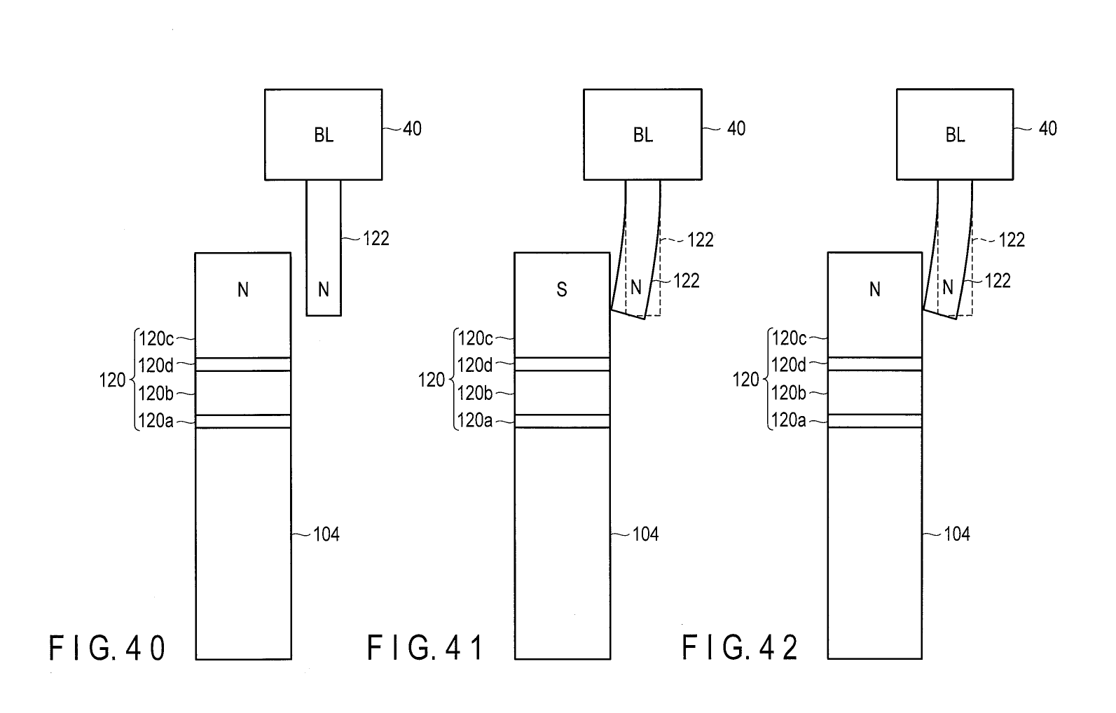

Referring first to FIGS. 39 and 40, the read operation will be described. In FIGS. 39 and 40, the lower end of the movable member 122 is the N pole. FIG. 39 shows a case where the magnet pole of the upper end of the magnetic member 120 is the S pole, and FIG. 40 shows a case where the magnet pole of the upper end of the magnetic member 120 is the N pole.

In the case of FIG. 39, an attractive force is exerted between the magnetic member 120 and the movable member 122, whereby the lower end of the movable member 122 is brought into contact with the upper end of the magnetic member 120. As a result, the contact portion 104, the magnetic member 120 and the movable member 122 provide a current route. Further, the select transistor (formed of the word line 14 and the source/drain regions 12) is in the ON state. This realizes a low resistance state between the bit line (BL) 40 and the source line (SL) 18 shown in FIG. 38.

In the case of FIG. 40, a repulsive force is exerted between the magnetic member 120 and the movable member 122. As a result, the movable member 122 is out of contact with the magnetic member 120. Accordingly, the current route between the contact portion 104 and the movable member 122 is interrupted to thereby realize a high resistance state between the bit line (BL) 40 and the source line (SL) 18.

As is evident from the above, when the movable member 122 is in contact with the magnetic member 120, a low resistance state is realized between the bit line (BL) 40 and the source line (SL) 18, while when the movable member 122 is out of contact with the magnetic member 120, a high resistance state is realized between the bit line (BL) 40 and the source line (SL) 18. Consequently, by detecting the resistance between the bit line (BL) 40 and the source line (SL) 18, the information (0 or 1) stored in the magnetic element can be determined.

Referring then to FIGS. 41 and 42, the write operation will be described. In FIGS. 41 and 42, the lower end of the movable member 122 is the N pole.

Further, FIG. 41 shows a case where the magnet pole of the upper end of the magnetic member 120 is the S pole, and FIG. 42 shows a case where the magnet pole of the upper end of the magnetic member 120 is the N pole.

In the case of FIG. 41, an attractive force is exerted between the magnetic member 120 and the movable member 122, whereby the lower end of the movable member 122 is brought into contact with the upper end of the magnetic member 120. In contrast, in the case of FIG. 42, a repulsive force is exerted between the magnetic member 120 and the movable member 122. During the write operation, however, a relatively high voltage (e.g., about 1V) is applied between the contact portion 104 and the movable member 122. Consequently, an electrostatic force is exerted between the magnetic member 120 and the movable member 122. If the electrostatic force (attractive force) exerted between the magnetic member 120 and the movable member 122 is set greater than the magnetic force (repulsive force) exerted therebetween, the magnetic member 120 and the movable member 122 can be made contact each other. Therefore, writing can be performed on the magnetic member 120 in both cases of FIGS. 41 and 42.

As described above, in the magnetic memory device of the third embodiment, the state in which the magnetic member 120 and the movable member 122 are separate from each other, or the state in which the magnetic member 120 and the movable member 122 are in contact with each other, can be selected in accordance with the magnetic force exerted between them.

Therefore, in the magnetic element of the third embodiment, the state in which the magnetic member 120 and the movable member 122 are separate from each other, and the state in which the magnetic member 120 and the movable member 122 are in contact with each other, can be associated with binary information (0 or 1). Thus, the third embodiment can provide a new magnetic memory device capable of storing binary information.

Further, in the magnetic memory device of the third embodiment, such an insulating layer as the tunnel barrier layer employed in the conventional magnetic elements does not exist between the lower and upper magnetic layers 120b and 120c of the magnetic member 120. This significantly reduces the resistance of the magnetic member 120, and therefore can set, to a low value, the resistance assumed in the low resistance state.

As a result, when a read operation is performed, the level of a read signal (e.g., the level of a read current) in the low resistance state can be increased, whereby a reliable read operation can be realized.

Furthermore, when a write operation is performed, it is performed on the magnetic member 120 that is set at a very low resistance value, with the result that a sufficient write current can be secured.

In addition, the magnetic element of the third embodiment does not have to use an insulating film, such as a tunnel barrier film, whose reliability is hard to secure, and therefore can enhance its reliability.

In the third embodiment, a noble metal film may be formed at a portion at which the magnetic member 120 and the movable member 122 contact each other, as in the first embodiment.

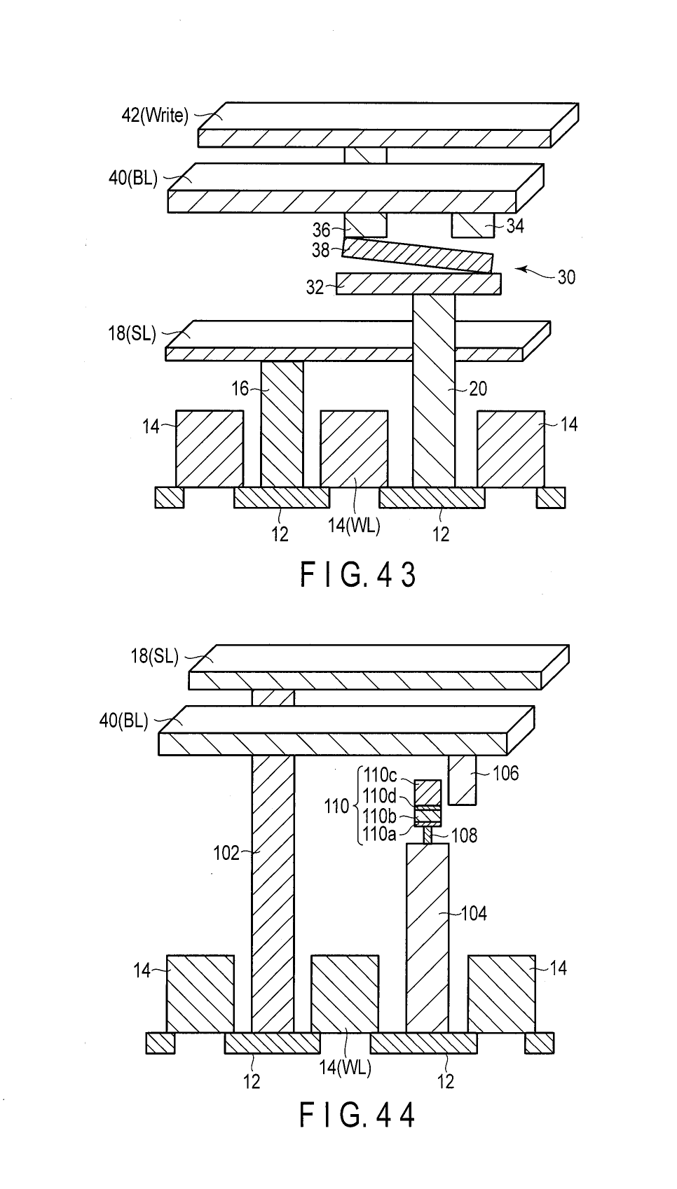

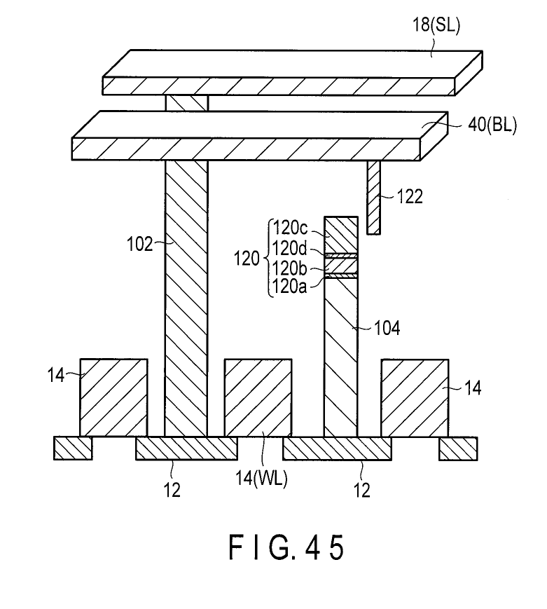

In the first, second and third embodiments described above, the select transistors shown in FIGS. 1, 33 and 38 have buried gate structures. However, select transistors may have normal gate structures as shown in FIGS. 43, 44 and 45.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising:
a first electrode;
a second electrode having magnetism and having a major surface facing a major surface of the first electrode;
a third electrode having a major surface facing the major surface of the first electrode and located away from the second electrode; and
a movable member having magnetism and located between the first and second electrodes and between the first and third electrodes, the movable member being able to be brought into contact with the first electrode and being able to be selectively brought into contact with one of the second and third electrodes.

2. The magnetic memory device of claim 1, wherein the third electrode has magnetism.

3. The magnetic memory device of claim 2, wherein a magnetic pole on the major surface side of the second electrode differs from a magnetic pole on the major surface side of the third electrode.

4. The magnetic memory device of claim 1, wherein
the movable member has a major surface facing the second and third electrodes; and
a magnetic pole on the major surface side of the movable member is variable.

5. The magnetic memory device of claim 1, wherein the movable member is surrounded by a space.

6. The magnetic memory device of claim 1, wherein the movable member has perpendicular magnetization.

7. The magnetic memory device of claim 1, wherein the movable member comprises:
a first magnetic layer;
a second magnetic layer which can be selectively brought into contact with one of the second and third electrodes; and
a nonmagnetic layer interposed between the first and second magnetic layers.

8. The magnetic memory device of claim 7, wherein the first magnetic layer has fixed magnetization and the second magnetic layer has variable magnetization.

9. The magnetic memory device of claim 1, further comprising:
a first line electrically connectable to the first electrode;
a second line electrically connectable to the second electrode; and
a third line electrically connectable to the third electrode.

10. The magnetic memory device of claim 9, further comprising a switching element connected to the third line.

11. The magnetic memory device of claim 10, wherein the switching element is in an OFF state during a read operation, and is in an ON state during a write operation.

12. The magnetic memory device of claim 1, wherein at least one of the major surface of the first electrode, the major surface of the second electrode, the major surface of the third electrode, a major surface of the movable member facing the first electrode, and a major surface of the movable member facing the second and third electrodes is formed of a noble metal.

13. A magnetic memory device comprising:
a first magnetic member; and
a second magnetic member,
wherein the magnetic memory device selectively exhibits one of a state in which the first and second magnetic members are separate from each other, and a state in which the first and second magnetic members are in contact with each other in accordance with a magnetic force exerted between the first and second magnetic members.

14. The magnetic memory device of claim 13, wherein
the first magnetic member is fixed; and
the second magnetic member is movable.

15. The magnetic memory device of claim 14, wherein the second magnetic member comprises:
a first magnetic layer;
a second magnetic layer which can be brought into contact with the first magnetic member; and
a nonmagnetic layer interposed between the first and second magnetic layers.

16. The magnetic memory device of claim 15, wherein the first magnetic layer has fixed magnetization, and the second magnetic layer has variable magnetization.

17. The magnetic memory device of claim 14, wherein the first magnetic member comprises:
a first magnetic layer;
a second magnetic layer which can be brought into contact with the second magnetic member; and
a nonmagnetic layer interposed between the first and second magnetic layers.

18. The magnetic memory device of claim 17, wherein the first magnetic layer has fixed magnetization, and the second magnetic layer has variable magnetization.

19. The magnetic memory device of claim 14, wherein the second magnetic member is surrounded by a space.

20. The magnetic memory device of claim 13, wherein the first and second magnetic members can be brought into contact with each other by an electrostatic force occurring between the first and second magnetic members.
